(19) United States
(12) Patent Application Publication
(10) Pub. No.: US 2018/0372810 A1
(43) Pub. Date: Dec. 27, 2018

(54) Magnetic Sensor Device, Self-Calibration Methods And Current Sensor

(71) Applicant: Aceinna Transducer Systems Co., Ltd., Wuxi (CN)

(72) Inventors: Leyue Jiang, Wuxi (CN); Yang Zhao, Andover, MA (US); Alexander Dribinsky, Gibsonia, PA (US); Akhil Garlapati, Lexington, MA (US); Dalai Li, Gibsonia, PA (US); Zhengwei Huang, Gibsonia, PA (US)

(21) Appl. No.: 16/013,539

(22) Filed: Jun. 20, 2018

(30) Foreign Application Priority Data
Jun. 26, 2017 (CN) 201710492932.6

(51) Int. Cl. G01R 33/00; G01R 33/09; G01R 33/07

(52) U.S. Cl. CPC G01R 33/0035; G01R 33/07; G01R 33/09

(57) ABSTRACT

A method involves a first magnetic sensor of a magnetic apparatus measuring an external magnetic field. The method also involves a signal processing circuit of the apparatus performing calibration using a second sensor in response to the external magnetic field. The first sensor and the second sensor are formed on the same substrate. There will be at least one magnetic sensor is used to measure the external magnetic field, and the other magnetic sensor is used in calibration, and therefore, the method ensures an effective output signal can be generated during calibration and enhances the accuracy of the measurement.

### CROSS-REFERENCE TO RELATED APPLICATION

The present disclosure claims the priority benefit of China Patent Application No. 201710492932.6, filed on 26 Jun. 2017, the content of which is incorporated by reference in its entirety.

### TECHNICAL FIELD

The present disclosure generally relates to techniques of magnetic sensor and, more particularly, to a magnetic sensing apparatus and self-calibration methods, current sensor and sensing apparatus using the same.

### BACKGROUND

The performance of magnetic sensors changes with the environment and time. In current technology, the magnetic sensors often have self-calibration functions. Taking magnetorestance (MR) sensor as an example, the Set/Reset function of an MR sensor can be used to calibrate a zero signal of the sensor and self-detect current coils to calibrate the sensitivity thereof. However, during calibration, the output signals will be affected. In addition, during the Set/Rest process, the output magnetic field signal will change the accuracy of calibration of the zero signal.

Therefore, there is a need for a new solution to solve the aforementioned problem.

### SUMMARY

This section is for the purpose of summarizing some aspects of the present disclosure and to briefly introduce some preferred embodiments. Simplifications or omissions in this section as well as in the abstract or the title of this description may be made to avoid obscuring the purpose of this section, the abstract and the title. Such simplifications or omissions are not intended to limit the scope of the present disclosure.

An aspect of the present disclosure is to provide a magnetic sensing apparatus and self-calibration methods using two magnetic sensors to ensure that during calibration the magnetic sensor may provide effective output signal and also enhance calibration accuracy.

To perform the above purpose, an aspect of the present disclosure to solve the above issue is to provide a self-calibration method of magnetic sensing apparatus, wherein the magnetic sensing apparatus comprises a first magnetic sensor, a second magnetic sensor, and a signal processing circuit. The first magnetic sensor and the second magnetic sensor can form on a same substrate. A method involves a signal processing circuit of the apparatus performing measurement using at least one magnetic sensor of the apparatus in response to an external magnetic field, and performing calibration using other magnetic sensor of the apparatus in calibration.

In some embodiments, when the first magnetic sensor is used in calibration, the second magnetic sensor measures an external magnetic field; when the second magnetic sensor is used in calibration, the first magnetic sensor measures the external magnetic field. When the second magnetic sensor is used in calibration, the first magnetic sensor measures the external magnetic field, and then the second magnetic sensor conducts SET operation. Adding a self-detection current upon a self-detection coils of the second magnetic sensor to calibrate a sensitivity of the second magnetic sensor to S2, and then the output signal of the first magnetic sensor is V_{A}=V_{A0}+S2*H, wherein V_{A0} denotes a zero signal of the first magnetic sensor and H is the external magnetic field. The signal processing circuit is used to adjust the output signal of the second magnetic sensor to V_{A}, and then the output signal of the second magnetic sensor is V_{B1}=V_{A0}+S2*H. The second magnetic sensor is used to conduct the SET operation, and then the output signal of the second magnetic sensor is V_{B2}=V_{A0}−S2*H, wherein V_{A0}=(V_{B1}+V_{B2})/2 and H=(V_{B1}−V_{B2})/(2*S2), to obtain V_{A0} after calibration and also the value of the external magnetic field. The second magnetic sensor is used to conduct SET operation, wherein the first magnetic sensor is used in calibration and the second magnetic sensor is used to conduct the measurement of the external magnetic field, and then the first magnetic sensor conducts the SET operation. By adding a self-detection current upon self-detection coils to calibrate the sensitivity of the first magnetic sensor to S1, the output signal of the second magnetic sensor is V_{B}=V_{B0}+S1*H, wherein V_{B0} denotes a zero signal of the second magnetic sensor, and H denotes the external magnetic field. The signal processing circuit is used to adjust the output signal of the first magnetic sensor to V_{B}, and then the output signal of the first magnetic sensor is V_{A1}=V_{B0}+S1*H. The first magnetic sensor is used to conduct SET operation, and then the output signal of the first magnetic sensor is V_{A2}=V_{B0}−S1*H, wherein V_{B0}=(V_{A1}+V_{A2})/2 and H=(V_{A1}−V_{A2})/(2*S1), to obtain V_{B0} after calibration and also the value of the external magnetic field. The first magnetic sensor is then used to conduct SET operation.

In some embodiments, the first magnetic sensor is used to continue the measurement, and the second magnetic sensor is used in calibration. The first magnetic sensor is used to conduct the measurement of the external magnetic field, and the second magnetic sensor is used in calibration, and then the second magnetic sensor conducts the SET operation. Adding a self-detection current upon a self-detection coils of the second magnetic sensor to calibrate a sensitivity of the second magnetic sensor to S2, and then the output signal of the first magnetic sensor is V_{A}=V_{A0}+S2*H, wherein V_{A0} denotes a zero signal of the first magnetic sensor and H denotes the external magnetic field. A signal processing circuit is used to adjust the output signal of the second magnetic sensor to V_{A}, and then the output signal of the second magnetic sensor is V_{B2}=V_{A0}−S2*H, wherein V_{A0}=(V_{B1}+V_{B2})/2 and H=(V_{B1}−V_{B2})/(2*S2) to obtain V_{A0} after calibration and also the value of the external magnetic field. A second magnetic sensor is then used to conduct SET operation.

An aspect of the present disclosure is to provide a magnetic sensing apparatus comprising a first magnetic sensor, a second magnetic sensor, and a signal processing circuit, wherein the first magnetic sensor and the second magnetic sensor can be formed on a same substrate. A method involves a signal processing circuit of the apparatus performing measurement using at least one magnetic sensor of the apparatus in response to an external magnetic field, and performing calibration using other magnetic sensor of the apparatus in calibration.

In some embodiments, when a first magnetic sensor is used to conduct calibration, a second magnetic sensor is used to conduct the measurement of the external magnetic field; when the second magnetic sensor is used to conduct calibration, the first magnetic sensor is used to conduct the measurement of an external magnetic field. When the second magnetic sensor is used to conduct calibration, the first magnetic sensor is used to conduct the measurement of the external magnetic field, and then the second magnetic sensor conducts the SET operation. Adding a self-detection current upon a self-detection coils of the second magnetic sensor to calibrate a sensitivity of the second magnetic sensor to S2, and then the output signal of the first magnetic sensor is V_{A}=V_{A0}+S2*H, wherein V_{A0} denotes a zero signal of the first magnetic sensor and H denotes the external magnetic field. A signal processing circuit is used to adjust the output signal of the second magnetic sensor to V_{A}, and then the output signal of the second magnetic sensor is V_{B2}=V_{A0}−S2*H, wherein V_{A0}=(V_{B1}+V_{B2})/2 and H=(V_{B1}−V_{B2})/(2*S2) to obtain V_{A0} after calibration and also the value of the external magnetic field. The second magnetic sensor is used to conduct SET operation, wherein the first magnetic sensor is used in calibration and the second magnetic sensor is used to conduct the measurement of an external field, and then the first magnetic sensor conducts the SET operation. Adding a self-detection current upon self-detection coils of the first magnetic sensor to calibrate a sensitivity of the first magnetic sensor to S1, and then the output signal of a second magnetic sensor is V_{B}=V_{B0}+S1*H, wherein V_{B0} denotes a zero signal of the second magnetic sensor and H denotes the external magnetic field. A signal processing circuit is used to adjust the output signal of the first magnetic sensor to V_{A2}=V_{B0}−S1*H, wherein V_{B0}=(V_{A1}+V_{A2})/2 and H=(V_{A1}−V_{A2})/(2*S1) to obtain V_{B0} after calibration and also the value of the external magnetic field. The first magnetic sensor is then used to conduct SET operation.

In some embodiments, a first magnetic sensor is used to continue the measurement, and a second magnetic sensor is used in calibration. When the first magnetic sensor is used to conduct the measurement of an external magnetic field, the second magnetic sensor is used in calibration, and then the second magnetic sensor conducts the SET operation. a self-detection current is added upon self-detection coils of the second magnetic sensor to calibrate a sensitivity of the second magnetic sensor to S2, and then the output signal of the first magnetic sensor is V_{A}=V_{A0}+S2*H, wherein V_{A0} denotes a zero signal of the first magnetic sensor and H denotes the external magnetic field. A signal processing circuit is used to adjust the output signal of the second magnetic sensor to V_{A}, and then the output signal of the second magnetic sensor is V_{B1}=V_{A0}±S2*H. The second magnetic sensor is then used to conduct SET operation, and the output signal of the second magnetic sensor is V_{B2}=V_{A0}−S2*H, wherein V_{A0}=(V_{B1}+V_{B2})/2 and H=(V_{B1}−V_{B2})/(2*S2) to obtain V_{A0} after calibration and also the value of the external magnetic field. The second magnetic sensor is then used to conduct SET operation.

An aspect of the present disclosure is to provide a current sensor comprising a first connection portion, a second connection portion, and a middle area connected with the first connection portion and the second connection portion. That is, the first magnetic sensor and the second magnetic sensor of the illustrated magnetic sensor apparatus are all located either above or below the first connection portion, or two magnetic sensing units of the first magnetic sensor are respectively located on both sides of the middle area, and the second magnetic sensor is located either above or below both the first connection portion and the second connection portion.

Compared with existing technology, the magnetic sensing apparatus of the present disclosure applies two magnetic sensors and a signal processing circuit to alternatively calibrate two magnetic sensors or use one of these two magnetic sensors to calibrate the other one. This ensures that there will be at least one magnetic sensor used to measure. Simultaneously, the other magnetic sensor is used to calibrate the sensitivity and zero signal for enhancing high accuracy of the measurement.

### BRIEF DESCRIPTION OF THE DRAWINGS

These and other features, aspects, and advantages of the present disclosure will become better understood with regard to the following description, appended claims, and accompanying drawings.

FIG. 1 is a schematic diagram illustrating the principle of the self-calibration method of the first embodiment of the present disclosure.

FIG. 2 is a structural block diagram of the magnetic sensor of the first embodiment of the present disclosure.

FIG. 3 is a schematic diagram of the magnetic sensor of the first embodiment of the present disclosure.

FIG. 4 is a schematic diagram illustrating the principle of the magnetic sensor of the first implementation example of second embodiment of this disclosure.

FIG. 5 is a schematic diagram illustrating the principle of the magnetic sensor of the second implementation example of second embodiment of this disclosure

FIG. 6 is a schematic diagram of the current sensor of the magnetic sensor of the second embodiment of the present disclosure.

### DETAILED DESCRIPTION OF THE PREFERRED EMBODIMENTS

The detailed description of the present disclosure is presented largely in terms of procedures, steps, logic blocks, processing, or other symbolic representations that directly or indirectly resemble the operations of devices or systems contemplated in the present disclosure. These descriptions and representations are typically used by those skilled in the art to most effectively convey the substance of their work to others skilled in the art.

Reference herein to “one embodiment” or “an embodiment” means that a particular feature, structure, or characteristic described in connection with the embodiment can be comprised in at least one embodiment of the present disclosure. The appearances of the phrase “in one embodiment” in various places in the specification are not necessarily all referring to the same embodiment, nor are separate or alternative embodiments mutually exclusive of other embodiments. Further, the order of blocks in process flowcharts or diagrams or the use of sequence numbers representing one or more embodiments of the present disclosure do not inherently indicate any particular order nor imply any limitations in the present disclosure.

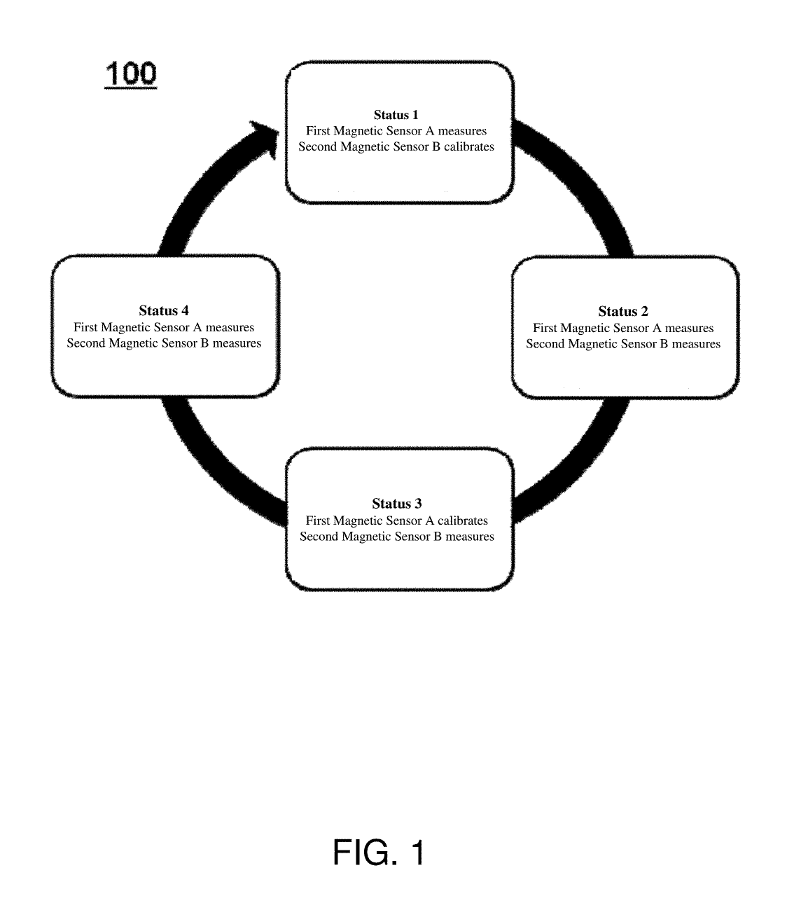

FIG. 1 illustrates a self-calibration method of magnetic sensing apparatus in the first embodiment in the present disclosure. The illustrated magnetic sensing apparatus comprises a first magnetic sensor, a second magnetic sensor, and a signal processing circuit, wherein the first magnetic sensor and the second magnetic sensor can be formed on a same substrate. The illustrated self-calibration method 100 comprises Status 1, Status 2, Status 3, and Status 4. In Status 1, the first magnetic sensor is used to measure an external magnetic field, and the second magnetic sensor is used in calibration; in Status 2, the first magnetic sensor is used in measurement, and the second magnetic sensor is used in measurement; in Status 3, the first magnetic sensor is used in calibration and the second magnetic sensor is used in measurement; in Status 4, the first magnetic sensor is used in measurement, and the second magnetic sensor is used in measurement. Therefore it assures that there will be at least one magnetic sensor is used into measurement, and the other magnetic sensor is used to calibrate the sensitivity and the zero signal and enhance the accuracy of the measurement. The first magnetic sensor and the second magnetic sensor can be AMR (Anisotropic Magneto Resistance) sensor, GMR (Giant Magneto Resistance) sensor, or TMR (Tunneling Magneto Resistance) sensor.

In Status 1, specific operations are performed as follow.

A second magnetic sensor is used to conduct SET operation.

A self-detection current is added upon self-detection coils of the second magnetic sensor to calibrate a sensitivity of the second magnetic sensor to S2, and then the output signal of the first magnetic sensor is V_{A}=V_{A0}+S2*H, wherein V_{A0} denotes a zero signal of the first magnetic sensor and H denotes the external magnetic field.

A signal processing circuit is used to adjust the output signal of a second magnetic sensor to V_{A}, and then the output signal of the second magnetic sensor is V_{B1}=V_{A0}+S2*H.

A second magnetic sensor is used to conduct RESET operation, and then the output signal of the second magnetic sensor is V_{B2}=V_{A0}−S2*H, wherein V_{A0}=(V_{B1}+V_{B2})/2 and H=(V_{B1}−V_{B2})/(2*S2), to obtain V_{A0} after calibration and also the value of the external magnetic field.

A second magnetic sensor is used to conduct SET operation.

in Status 3, specific operations are performed as follow:

A first magnetic sensor is used to conduct SET operation.

A self-detection current is added upon self-detection coils of a first magnetic sensor to calibrate the sensitivity of the first magnetic sensor to S1, and then the output signal of a second magnetic sensor is V_{B}=V_{B0}+S1*H, wherein V_{B0} denotes a zero signal of the second magnetic sensor and H denotes the external magnetic field.

A signal processing circuit is used to adjust the output signal of a first magnetic sensor to V_{B}, and then the output signal of the first magnetic sensor is V_{A1}=V_{B0}+S1*H;

A first magnetic sensor is used to conduct RESET operation, and then the output signal of the first magnetic sensor is V_{A2}=V_{B0}−S1*H, wherein V_{B0}=(V_{A1}+V_{A2})/2 and H=(V_{A1}−V_{A2})/(2*S1), to obtain V_{B0} after calibration and also the value of the external magnetic field.

A first magnetic sensor is used to conduct SET operation.

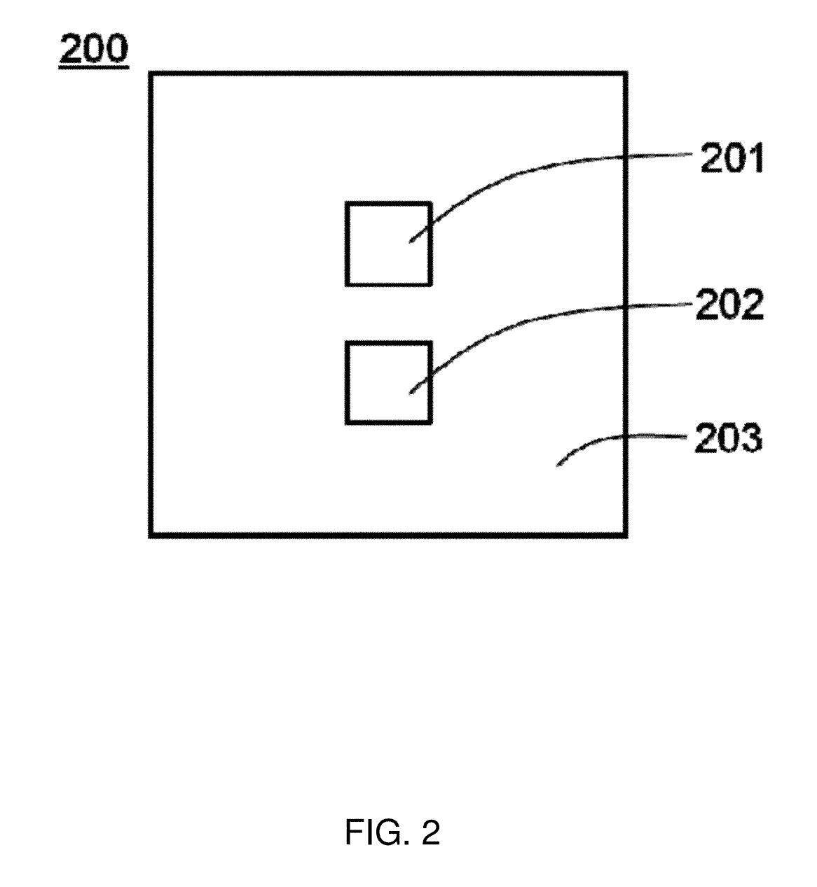

FIG. 2 illustrates a magnetic sensing apparatus of the first embodiment in the present disclosure. The illustrated magnetic sensing apparatus 200 comprises a substrate 203, a first magnetic sensor 201, and a second magnetic sensor 202, wherein the first magnetic sensor 201 and the second magnetic sensor 202 can form on a same substrate 203. The first magnetic sensor 201 and the second magnetic sensor 202 can be anisotropic magnetoresistance (AMR) sensor, giant magnetoresistance (GMR) sensor, or tunnel magnetoresistance (TMR) sensor. The first magnetic sensor 201 and the second magnetic sensor 202 can be alternatively used in calibration to ensure that there is at least one magnetic sensor is used in measurement, and other magnetic sensor is used to conduct the calibration of the sensitivity and zero signal and enhance high accuracy of the measurement.

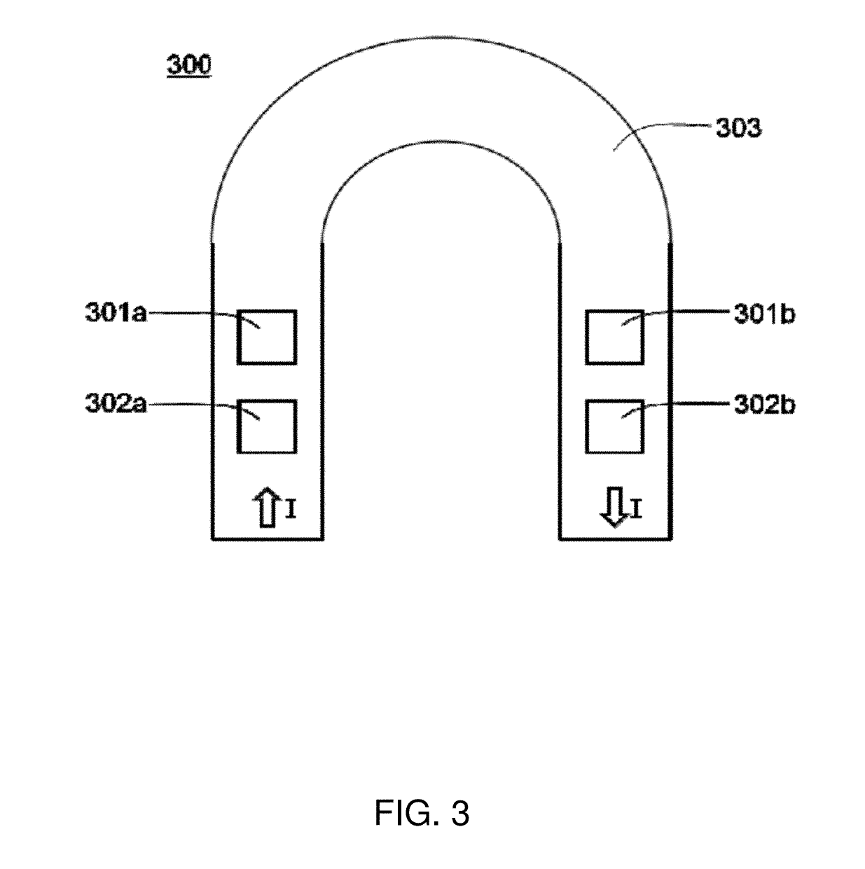

FIG. 3 illustrates a current sensor applying the magnetic sensing apparatus of the first embodiment in the present disclosure. A current sensor 300 comprises a U-shaped conductor 303, a first magnetic sensor 301, and second magnetic sensor 302. The U-shaped conductor 303 comprises a first connection portion, a second connection portion, and a middle area connected with the first connection portion and the second connection portion. The first magnetic sensor 301 comprises a magnetic sensing unit 301a and a magnetic sensing unit 301b, and the second magnetic sensor 302 comprises a magnetic sensing unit 302a and a magnetic sensing unit 302b. The U-shaped conductor 303 conducts the current I to generate a magnetic field within the magnetic sensor area. The magnetic sensors 301 and 302 can form on a same substrate. The magnetic sensors 301 and 302 can be ether anisotropic magnetoresistance (AMR) sensor, giant magnetoresistance (GMR) sensor, or tunnel magnetoresistance (TMR) sensor. The magnetic sensors 301 and 302 can be alternatively used in calibration to ensure that there is at least one magnetic sensor used in measurement, and other magnetic sensor is used to conduct the calibration of the sensitivity and zero signal and enhance the accuracy of the measurement.

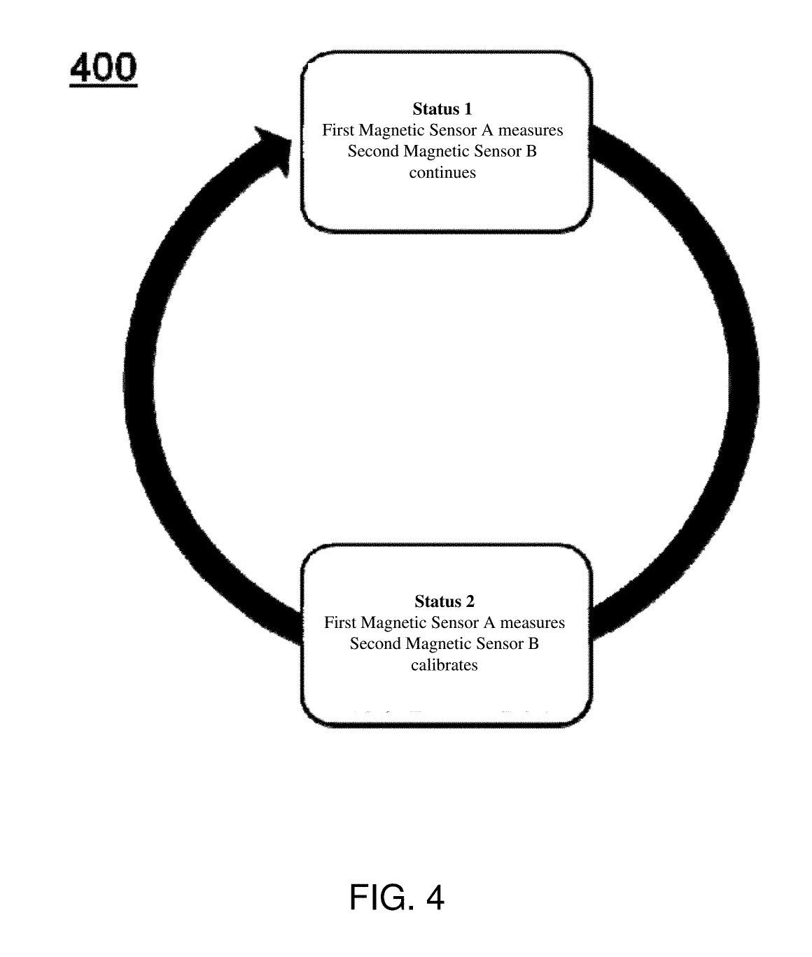

FIG. 4 illustrates a self-calibration method of the magnetic sensing apparatus of the second embodiment in the present disclosure. The illustrated magnetic sensing apparatus comprises a first magnetic sensor, a second magnetic sensor, and a signal processing circuit, wherein the first magnetic sensor and the second magnetic sensor can form on a same substrate. The illustrated self-calibration method 400 comprises Status 1 and Status 2. In Status 1, a first magnetic sensor is used to measure an external magnetic field, and a second magnetic sensor is used in calibration; in Status 2, the first magnetic sensor is used in measurement, and the second magnetic sensor is used in calibration. It ensures that the first magnetic sensor is used to continues the measurement, and simultaneously the second magnetic sensor is used to calibrate the zero signal of the first magnetic sensor to assure high accuracy of the measurement. The first magnetic sensor is Hall sensor, and the second magnetic sensor can be either anisotropic magnetoresistance (AMR) sensor, giant magnetoresistance (GMR) sensor, or tunnel magnetoresistance (TMR) sensor.

In Status 2, specific operations are performed as follow.

A second magnetic sensor is used to conduct a SET operation.

A self-detection current is added upon self-detection coils of a second magnetic sensor to calibrate the sensitivity of the second magnetic sensor to S2. Then the output signal of the first magnetic sensor is V_{A}=V_{A0}+S2*H, wherein V_{A0} denotes the zero signal of the first magnetic sensor, and H denotes an external magnetic field.

A signal processing circuit is used to adjust the output signal of a second magnetic sensor to V_{A}, and then the output signal of the second magnetic sensor is V_{B1}=V_{A0}+S2*H.

A second magnetic sensor is used to conduct RESET operation, and then the output signal of the second magnetic sensor is V_{B2}=V_{A0}−S2*H, wherein V_{A0}=(V_{B1}+V_{B2})/2 and H=(V_{B1}−V_{B2})/(2*S2), to obtain V_{A0} after calibration, and also the value of the external magnetic field.

A second magnetic sensor is used to conduct SET operation.

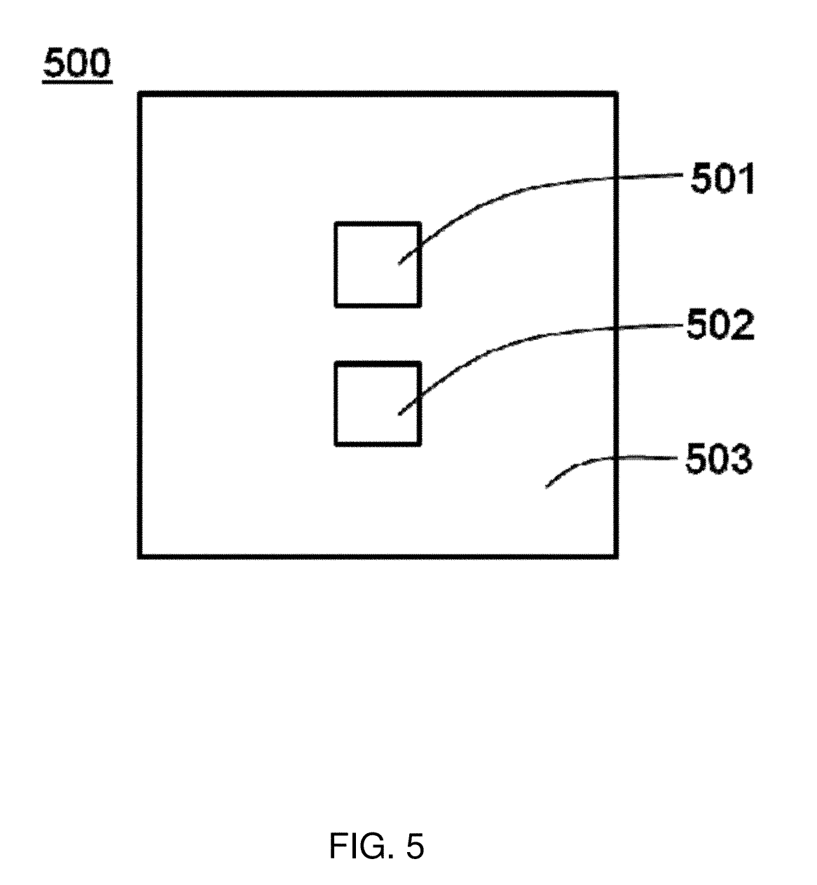

FIG. 5 shows the magnetic sensing apparatus of the second embodiment in the present disclosure. The illustrated magnetic sensing apparatus 500 comprises a substrate 503, a first magnetic sensor 501, and a second magnetic sensor 502, wherein the first magnetic sensor 501 and the second magnetic sensor 502 can form on a same substrate 503. The first magnetic sensor is Hall sensor, and the second magnetic sensor can be either anisotropic magnetoresistance (AMR) sensor, giant magnetoresistance (GMR) sensor, or tunnel magnetoresistance (TMR) sensor. The first magnetic sensor 501 is used to continue the measurement, and simultaneously the second magnetic sensor 502 is used to calibrate the zero signal of the first magnetic sensor and assure high accuracy of the measurement.

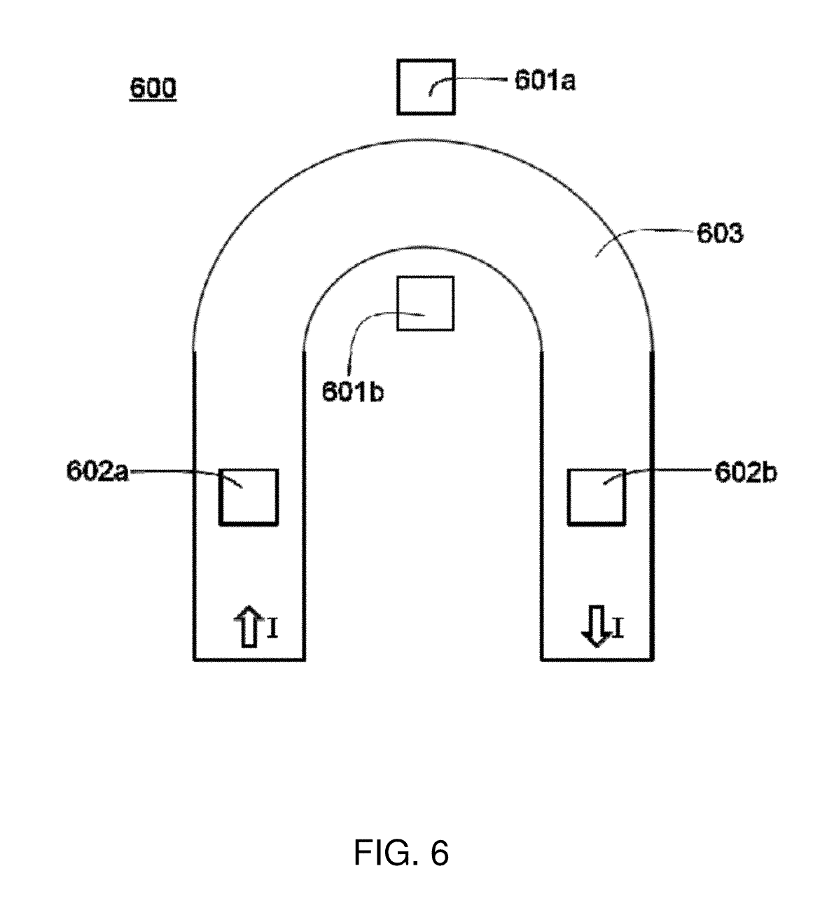

FIG. 6 shows a current sensor of the magnetic sensing apparatus of the second embodiment in the present disclosure. The illustrated current sensor 600 comprises a U-shaped conductor 603, a first magnetic sensor 601, and a second magnetic sensor 602. The first magnetic sensor 601 comprises a magnetic sensing unit 601a and a magnetic sensing unit 601b, and the second magnetic sensor 602 comprises a magnetic sensing unit 602a and a magnetic sensing unit 602. The U-shaped conductor 603 comprises a first connection portion, a second connection portion, and a middle area connected with the first connection portion and the second connection portion. The U-shaped conductor 603 conducts the current I to generate a magnetic field within the magnetic sensor area. The first magnetic sensor 601 and the second magnetic sensor 602 can form on a same substrate. The magnetic sensing units 601a and 601b of the first magnetic sensor are respectively located on both sides of the middle area, and the magnetic sensing units 602a and 602b of the second magnetic sensor are respectively located above or below the first connection portion and the second connection portion. The first magnetic sensor 601 is Hall sensor, and the second magnetic sensor 602 can be ether anisotropic magnetoresistance (AMR) sensor, giant magnetoresistance (GMR) sensor, or tunnel magnetoresistance (TMR) sensor. The first magnetic sensor 601 and the second magnetic sensor 602 can detect the magnetic field generated by the current in the U-shaped conductor 603. The magnetic sensor 601 is used to continue the measurement, and simultaneously the magnetic sensor 602 is used to calibrate the zero signal of the magnetic sensor 601 to assure the accuracy of the measurement.

It should be noted that any modification made by a person skilled in the art to the embodiments disclosed in the present disclosure would still be considered within the scope of the claims of the present application. Accordingly, the scope of the claims of the present application is not limited to the foregoing embodiments.

### ADDITIONAL NOTES

The herein-described subject matter sometimes illustrates different components contained within, or connected with, different other components. It is to be understood that such depicted architectures are merely examples, and that in fact many other architectures can be implemented which achieve the same functionality. In a conceptual sense, any arrangement of components to achieve the same functionality is effectively “associated” such that the desired functionality is achieved. Hence, any two components herein combined to achieve a particular functionality can be seen as “associated with” each other such that the desired functionality is achieved, irrespective of architectures or intermedial components. Likewise, any two components so associated can also be viewed as being “operably connected”, or “operably coupled”, to each other to achieve the desired functionality, and any two components capable of being so associated can also be viewed as being “operably couplable”, to each other to achieve the desired functionality. Specific examples of operably couplable include but are not limited to physically mateable and/or physically interacting components and/or wirelessly interactable and/or wirelessly interacting components and/or logically interacting and/or logically interactable components.

Further, with respect to the use of substantially any plural and/or singular terms herein, those having skill in the art can translate from the plural to the singular and/or from the singular to the plural as is appropriate to the context and/or application. The various singular/plural permutations may be expressly set forth herein for sake of clarity.

Moreover, it will be understood by those skilled in the art that, in general, terms used herein, and especially in the appended claims, e.g., bodies of the appended claims, are generally intended as “open” terms, e.g., the term “including” should be interpreted as “including but not limited to,” the term “having” should be interpreted as “having at least,” the term “includes” should be interpreted as “includes but is not limited to,” etc. It will be further understood by those within the art that if a specific number of an introduced claim recitation is intended, such an intent will be explicitly recited in the claim, and in the absence of such recitation no such intent is present. For example, as an aid to understanding, the following appended claims may contain usage of the introductory phrases “at least one” and “one or more” to introduce claim recitations. However, the use of such phrases should not be construed to imply that the introduction of a claim recitation by the indefinite articles “a” or “an” limits any particular claim containing such introduced claim recitation to implementations containing only one such recitation, even when the same claim includes the introductory phrases “one or more” or “at least one” and indefinite articles such as “a” or “an,” e.g., “a” and/or “an” should be interpreted to mean “at least one” or “one or more;” the same holds true for the use of definite articles used to introduce claim recitations. In addition, even if a specific number of an introduced claim recitation is explicitly recited, those skilled in the art will recognize that such recitation should be interpreted to mean at least the recited number, e.g., the bare recitation of “two recitations,” without other modifiers, means at least two recitations, or two or more recitations. Furthermore, in those instances where a convention analogous to “at least one of A, B, and C, etc.” is used, in general such a construction is intended in the sense one having skill in the art would understand the convention, e.g., “a system having at least one of A, B, and C” would include but not be limited to systems that have A alone, B alone, C alone, A and B together, A and C together, B and C together, and/or A, B, and C together, etc. In those instances where a convention analogous to “at least one of A, B, or C, etc.” is used, in general such a construction is intended in the sense one having skill in the art would understand the convention, e.g., “a system having at least one of A, B, or C” would include but not be limited to systems that have A alone, B alone, C alone, A and B together, A and C together, B and C together, and/or A, B, and C together, etc. It will be further understood by those within the art that virtually any disjunctive word and/or phrase presenting two or more alternative terms, whether in the description, claims, or drawings, should be understood to contemplate the possibilities of including one of the terms, either of the terms, or both terms. For example, the phrase “A or B” will be understood to include the possibilities of “A” or “B” or “A and B.”

From the foregoing, it will be appreciated that various implementations of the present disclosure have been described herein for purposes of illustration, and that various modifications may be made without departing from the scope and spirit of the present disclosure. Accordingly, the various implementations disclosed herein are not intended to be limiting, with the true scope and spirit being indicated by the following claims.

What is claimed is:

1. A self-calibration method of a magnetic sensing apparatus, comprising:
measuring, by one of a first magnetic sensor and a second magnetic sensor of a magnetic sensing apparatus, an external magnetic field; and
performing, by a signal processing circuit of the magnetic sensing apparatus, calibration using the other of the first magnetic sensor and the second magnetic sensor of the magnetic sensing apparatus responsive to the measuring,
wherein the first magnetic sensor and the second magnetic sensor are formed on a same substrate.

2. The self-calibration method of claim 1, wherein:
in an event that the first magnetic sensor is used in the calibration, the external magnetic field is measured using the second magnetic sensor; and
in an event that the second magnetic sensor is used in the calibration, the external magnetic field is measured using the first magnetic sensor.

3. The self-calibration method of claim 2, further comprising:
in an event that the second magnetic sensor is used in the calibration and the first magnetic sensor is used in measuring the external magnetic field, performing:
performing a SET operation using the second magnetic sensor;
adding a self-detection current upon self-detection coils of the second magnetic sensor to calibrate a sensitivity of the second magnetic sensor to S2 wherein an output signal of the first magnetic sensor is V_{A}=V_{A0}+S2*H, wherein V_{A0} denotes a zero signal of the first magnetic sensor and H denotes the external magnetic field;
adjusting, by the signal processing circuit, an output signal of the second magnetic sensor to V_{A}, wherein the output signal of the second magnetic sensor is V_{B1}=V_{A0}+S2*H;
performing a RESET operation using the second magnetic sensor, wherein the output signal of the second magnetic sensor is V_{B2}=V_{A0}−S2*H, with V_{A0}=(V_{B1}+V_{B2})/2 and H=(V_{B1}−V_{B2})/(2*S2), to obtain V_{A0} after calibration and also a value of the external magnetic field; and
performing the SET operation using the second magnetic sensor,
in an event that the first magnetic sensor is used in the calibration and the second magnetic sensor is used in measuring the external magnetic field, performing:
performing the SET operation using the first magnetic sensor;
adding a self-detection current upon self-detection coils of the first magnetic sensor to calibrate a sensitivity of the first magnetic sensor to S1 wherein the output signal of the second magnetic sensor is V_{B}=V_{B0}+S1*H, wherein V_{B0} denotes a zero signal of the second magnetic sensor and H denotes the external magnetic field;
adjusting, by the signal processing circuit, the output signal of the first magnetic sensor to V_{B}, wherein the output signal of the first magnetic sensor is V_{A1}=V_{B0}+S1*H;
performing a RESET operation using the first magnetic sensor, wherein the output signal of the first magnetic sensor is V_{A2}=V_{B0}−S1*H, with V_{B0}=(V_{A1}+V_{A2})/2 and H=(V_{A1}−V_{A2})/(2*S1), to obtain V_{B0} after calibration and a value of the external magnetic field; and
performing the SET operation using the first magnetic sensor.

4. The magnetic sensors used in self-calibration method of claim 2, wherein each of the first magnetic sensor and the second magnetic sensor comprises an anisotropic magnetoresistance (AMR) sensor, a giant magnetoresistance (GMR) sensor, or a tunnel magnetoresistance (TMR) sensor.

5. The self-calibration method of claim 1, wherein the first magnetic sensor is continuously used for the measuring and the second magnetic sensor is used for the calibration.

6. The self-calibration method of claim 5, further comprising:
in an event that the first magnetic sensor is used in measuring the external magnetic field and the second magnetic sensor is used in the calibration, performing:
performing a SET operation using the second magnetic sensor;
adding a self-detection current upon self-detection coils of the second magnetic sensor to calibrate a sensitivity of the second magnetic sensor to S2, wherein an output signal of the first magnetic sensor is V_{A}=V_{A0}±S2*H, wherein V_{A0} denotes a zero signal of the first magnetic sensor and H denotes the external magnetic field;
adjusting, by the signal processing circuit, an output signal of the second magnetic sensor to V_{A}, wherein the output signal of the second magnetic sensor is V_{B1}=V_{A0}+S2*H;
performing a RESET operation by the second magnetic sensor, wherein the output signal of the second magnetic sensor is V_{B2}=V_{A0}−S2*H, with V_{A0}=(V_{B1}+V_{B2})/2 and H=(V_{B1}−V_{B2})/(2*S2), to obtain V_{A0} after calibration and a value of the external magnetic field; and
performing the SET operation using the second magnetic sensor.

7. Two magnetic sensors of claim 5, wherein the first magnetic sensor comprises a Hall sensor, and wherein the second magnetic sensor comprises an anisotropic magnetoresistance (AMR) sensor, a giant magnetoresistance (GMR) sensor, or a tunnel magnetoresistance (TMR) sensor.

8. A magnetic sensing apparatus, comprising:
a first magnetic sensor;
a second magnetic sensor; and
a signal processor circuit,
wherein the first magnetic sensor and the second magnetic sensor are formed on a same substrate, and
wherein, when one of the first magnetic sensor and the second magnetic sensor measures an external magnetic field, the signal processing circuit performs calibration by using the other of the first magnetic sensor and the second magnetic sensor.

9. The magnetic sensing apparatus of claim 8,
in an event that the first magnetic sensor is used in the calibration, the external magnetic field is measured using the second magnetic sensor; and
in an event that the second magnetic sensor is used in the calibration, the external magnetic field is measured using the first magnetic sensor.

10. The magnetic sensing apparatus of claim 9, further comprising:
in an event that the second magnetic sensor is used in the calibration and the first magnetic sensor is used in measuring the external magnetic field, performing:
performing a SET operation using the second magnetic sensor;
adding a self-detection current upon self-detection coils of the second magnetic sensor to calibrate a sensitivity of the second magnetic sensor to S2 wherein an output signal of the first magnetic sensor is V_{A}=V_{A0}+S2*H, wherein V_{A0} denotes a zero signal of the first magnetic sensor and H denotes the external magnetic field;
adjusting, by the signal processing circuit, an output signal of the second magnetic sensor to V_{A}, wherein the output signal of the second magnetic sensor is V_{B1}=V_{A0}+S2*H;
performing a RESET operation using the second magnetic sensor, wherein the output signal of the second magnetic sensor is V_{B2}=V_{A0}−S2*H, with V_{A0}=(V_{B1}+V_{B2})/2 and H=(V_{B1}−V_{B2})/(2*S2), to obtain V_{A0} after calibration and a value of the external magnetic field; and
performing the SET operation using the second magnetic sensor,
in an event that the first magnetic sensor is used in the calibration and the second magnetic sensor is used in measuring the external magnetic field, performing:
performing the SET operation using the first magnetic sensor;
adding a self-detection current upon self-detection coils of the first magnetic sensor to calibrate a sensitivity of the first magnetic sensor to S1 wherein the output signal of the second magnetic sensor is V_{B}=V_{B0}+S1*H, wherein V_{B0} denotes a zero signal of the second magnetic sensor and H denotes the external magnetic field;
adjusting, by the signal processing circuit, the output signal of the first magnetic sensor to V_{B}, wherein the output signal of the first magnetic sensor is V_{A1}=V_{B0}+S1*H;
performing a RESET operation using the first magnetic sensor, wherein the output signal of the first magnetic sensor is V_{A2}=V_{B0}−S1*H, with V_{B0}=(V_{A1}+V_{A2})/2 and H=(V_{A1}−V_{A2})/(2*S1), to obtain V_{B0} after calibration and a value of the external magnetic field; and
performing the SET operation using the first magnetic sensor.

11. The magnetic sensing apparatus of claim 8, wherein the first magnetic sensor is continuously used for the measuring and the second magnetic sensor is used for the calibration.

12. The magnetic sensing apparatus of claim 11, further comprising:
in an event that the first magnetic sensor is used in measuring the external magnetic field and the second magnetic sensor is used in the calibration, performing:
performing a SET operation using the second magnetic sensor;
adding a self-detection current upon self-detection coils of the second magnetic sensor to calibrate a sensitivity of the second magnetic sensor to S2, wherein an output signal of the first magnetic sensor is V_{A}=V_{A0}±S2*H, wherein V_{A0} denotes a zero signal of the first magnetic sensor and H denotes the external magnetic field;
adjusting, by the signal processing circuit, an output signal of the second magnetic sensor to V_{A}, wherein the output signal of the second magnetic sensor is V_{B1}=V_{A0}+S2*H;
performing a RESET operation by the second magnetic sensor, wherein the output signal of the second magnetic sensor is V_{B2}=V_{A0}−S2*H, with V_{A0}=(V_{B1}+V_{B2})/2 and H=(V_{B1}−V_{B2})/(2*S2), to obtain V_{A0} after calibration and a value of the external magnetic field; and
performing the SET operation using the second magnetic sensor.

13. A current sensor, comprising:
a U-shaped conductor comprising a first connection portion, a second connection portion, and a middle area connected with the first connection portion and the second connection portion; and
a magnetic sensing apparatus comprising:
a first magnetic sensor;
a second magnetic sensor; and
a signal processor circuit,
wherein the first magnetic sensor and the second magnetic sensor are formed on a same substrate,
wherein, when one of the first magnetic sensor and the second magnetic sensor measures an external magnetic field, the signal processing circuit performs calibration by using the other of the first magnetic sensor and the second magnetic sensor, and
wherein, either:
the first magnetic sensor and the second magnetic sensor are located either above or below the first connection portion; or
two magnetic sensing units of the first magnetic sensor are respectively located on both sides of the middle area, and the second magnetic sensor is located either above or below the first connection portion and the second connection portion.
